(19) United States
(12) Patent Application Publication
(10) Pub. No.: US 2006/0094198 A1
(43) Pub. Date: May 4, 2006

(54) Integrated analog circuit using switched capacitor technology

(76) Inventors: Hagen Klauk, Stuttgart (DE); Marcus Halik, Erlangen (DE); Ute Zschieschang, Stuttgart (DE); Dirk Rohde, Leipzig (DE); Gunter Schmid, Hemhofen (DE); Ralf Brederlow, Poing (DE)

Correspondence Address: EDELL, SHAPIRO & FINNAN, LLC, 1901 RESEARCH BLVD., SUITE 400, ROCKVILLE, MD, 20850, US

(21) Appl. No.: 11/257,402

(22) Filed: Oct. 25, 2005

(30) Foreign Application Priority Data
Oct. 27, 2004 (DE) 102004052266.9

(51) Int. Cl. H01L 21/20

(52) U.S. Cl. 438/382

(57) ABSTRACT

An integrated analog circuit using switched capacitor technology includes an integrated capacitor device that includes a first electrode device, a second electrode device, and a dielectric region formed between the first and second electrode devices. The dielectric region is made from or with an organic material.

### CROSS REFERENCE TO RELATED APPLICATIONS

This application claims priority under 35 USC §119 to German Application No. DE 10 2004 052 266.9, filed on Oct. 27, 2004, and titled “Integrated Analog Circuit Using Switched Capacitor Technology and Method for Producing It,” the entire contents of which are hereby incorporated by reference.

### FIELD OF THE INVENTION

The present invention relates to an integrated analog circuit using switched capacitor technology and to a method for producing an integrated analog circuit using switched capacitor technology. In particular, the present invention relates to analog circuits using switched capacitor technology on the basis of organic semiconductors and polymeric or molecular dielectrics.

### BACKGROUND

In the further development of modem circuit technologies, attention is increasingly being focused on aspects of flexibility in addition to aspects of miniaturization and large scale integration. Specific applications in which capacitors and capacitor devices play a crucial part can no longer be circumscribed on the basis of conventional semiconductor materials and the processing techniques thereof on account of the demands with regard to a flexible configuration and also for cost reasons.

### SUMMARY OF THE INVENTION

An object of the invention is to provide an integrated analog circuit using switched capacitor technology and, moreover, a corresponding production method in which integrated capacitor devices and corresponding integrated analog circuits using switched capacitor technology can be provided in a particularly simple and nevertheless reliable and indeed cost-effective manner.

The above and further objects of the invention are achieved in accordance with the present invention for integrated analog circuits using switched capacitor technology, and also for the production of an integrated capacitor device or for an integrated analog circuit using switched capacitor technology.

In accordance with the present invention, an integrated analog circuit using switched capacitor technology comprises an integrated capacitor device that includes a first electrode device, a second electrode device, and a dielectric region formed between the first and second electrode devices. The dielectric region is made from or with an organic material.

In one embodiment of the present invention, an integrated analog circuit using switched capacitor technology is formed with a capacitor device and with a transistor device that is connected to the capacitor device. For the integrated capacitor device, a dielectric region is provided between a first electrode device and a second electrode device. According to the invention, the integrated capacitor device is formed with or from at least one organic material. In accordance with the present invention, an integrated capacitor device of an analog circuit using switched capacitor technology includes a dielectric region that is formed from or with an organic material.

This opens up a multiplicity of new materials which exhibit beneficial properties and which surpass the materials that normally form the basis of integrated capacitor devices, and surpass the properties of said materials, in terms of flexibility and in terms of the breadth of the spectrum of use. In addition, the layer thickness of the dielectric region can be effectively controlled and/or be formed with particularly small dimensions.

In one embodiment of the invention, the dielectric region of the analog circuit includes an organic material formed with or from at least one organic polymeric dielectric material.

It is advantageous if, as an alternative or in addition, the organic material of the dielectric region is formed with or from at least one organic molecular dielectric, in particular in the form of at least one self-assembled monomolecular layer or an SAM.

The organic material of the dielectric region can also be formed with or from at least one thermally crosslinked organic material.

In a preferred embodiment, the organic material of the dielectric region is formed with or from at least one optically crosslinked organic material.

The first electrode device and/or the second electrode device may be formed with or from at least one metallic material.

In one preferred embodiment of the integrated analog circuit according to the invention, the analog circuit is formed on or in a substrate, in particular on or in the surface region of the substrate. The substrate can be formed with or from at least one material from the group consisting of a glass, a mechanically flexible material, a film and polymer film.

In one preferred embodiment of the integrated analog circuit according to the invention, in addition or as an alternative, the transistor device is formed with or on the basis of at least one organic material. Alternatively, a transistor can also be formed on the basis of a conventional semiconductor technology, e.g. a silicon technology, in accordance with the invention.

As an alternative or in addition, the transistor device is formed with a channel region made from or with at least one organic semiconductor material, in particular with or from at least one material formed from pentacene, polythiophene and oligothiophene.

In another alternative or additional embodiment, a gate insulation region is provided between a channel region and a gate electrode of the transistor device, where the gate insulation region includes or is made from at least one organic material, in particular at least one material from the group formed by a polymeric dielectric material, a molecular dielectric and a self-assembling monolayer (SAM).

By way of example, the integrated analog circuit is formed as a low-pass filter.

In a further embodiment of the present invention, a method for producing an integrated analog circuit using switched capacitor technology is provided, where the integrated analog circuit is formed with a capacitor device and with a transistor device that is connected to the capacitor device. A dielectric region is provided for the capacitor device between a first electrode device and a second electrode device, where the dielectric region of the integrated capacitor device is formed with or from at least one organic material.

For example, the organic material of the dielectric region can be formed with or from at least one organic polymeric dielectric material. Alternatively, or in addition to the organic material of the dielectric region being formed from at least one organic polymeric dielectric material, the organic material of the dielectric region can be formed with or from at least one self-assembled monomolecular layer (SAM). The organic material of the dielectric region can also be formed with or from at least one thermally crosslinked organic material.

On the other hand, the organic material of the dielectric region may alternatively or additionally be formed with or from at lest one optically crosslinked organic material.

The first electrode device and/or the second electrode device are formed with or from at least one metallic material.

According to the invention, the integrated capacitor device can be formed on or in a substrate, in particular on or in the surface region of the substrate. The substrate can be formed with or from at least one material from the group consisting of a glass, a mechanically flexible material, a film and a polymer film.

In one preferred embodiment of the production method, the transistor device is formed with or on the basis of at least one organic material.

As an alternative, or in addition, the transistor device can be formed with a channel region made from or with at least one organic semiconductor material, in particular with or from at least one material from the group formed by pentacene, polythiophene and oligothiophene.

Furthermore, in addition or as an alternative, between a channel region and a gate electrode of the transistor device, a gate insulation region can be provided with or made from at least one organic material, in particular with or made from at least one material from the group formed by a polymeric dielectric material, a molecular dielectric material and a self-assembling monolayer (SAM).

The integrated analog circuit can be formed e.g. as a low-pass filter.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIG. 1A is a schematic and sectional side view of an embodiment of an integrated capacitor device according to the invention.

FIG. 1B is a graph illustrating the capacitance as a function of the frequency and further demonstrating dependence of the capacitance of an embodiment of the integrated capacitor device according to the invention on the frequency.

FIG. 2 is a schematic and sectional side view of an embodiment of an integrated capacitor device in an integrated analog circuit according to the invention.

FIG. 3A is a graph showing a current-voltage characteristic curve for an embodiment of the integrated capacitor device of the invention.

FIG. 3B is a graph showing a current-voltage characteristic curve of an embodiment of the integrated capacitor device according to the invention.

FIG. 4A is a schematic circuit diagram of a low-pass filter using switched capacitor technology, which is configured according to the invention, as a preferred embodiment of the integrated analog circuit according to the invention.

FIG. 4B depicts two graphs representing a phase diagram of the low-pass filter using switched capacitor technology as shown in FIG. 4A.

FIG. 5 is a schematic and sectional side view of another embodiment of the integrated capacitor device according to the invention.

FIG. 6 is a schematic illustration of an exemplary molecule that can be used for forming dielectric regions and, in particular, monolayers in a further embodiment of the integrated capacitor device according to the invention.

### DETAILED DESCRIPTION

The present invention relates, in particular, inter alia to analog circuits using switched capacitor technology on the basis of organic semiconductors and polymeric and/or molecular dielectric materials.

The scientific discovery that specific organic materials have semiconductor properties has very recently led to the development of a whole series of electronic applications. In comparison with inorganic semiconductors, such as silicon for example, organic semiconductors are distinguished by the fact that they can be obtained, purified and processed in the form of thin layers relatively simply and cost-effectively. Moreover, the layer deposition can generally be effected at temperatures that lie significantly below the process temperatures customary in silicon technology. These properties permit electronic components based on organic semiconductor layers to be fabricated cost-effectively on large-area, inexpensive and, if appropriate, even flexible substrates.

The electronic applications for organic semiconductor materials that can be realized at the current state of the art can in principle be classified as follows:
1. Organic light emitting diodes and organic photo detectors.
2. Switching elements in the form of organic diodes or organic field effect transistors for the electrical insulation and targeted driving of individual components or pixels in high-resolution flat screens, sensors and detectors.
3. Integrated circuits based on organic field effect transistors for the processing of digital signals or so-called organic digital circuits.

One category of applications that has not been realized satisfactorily with organic semiconductors at the current state of development is the category of integrated circuits for processing analog signals. This is because of the particular requirements that the realization of analog circuits demands of the individual components used.

In silicon technology, by way of example, demanding analog circuits are generally fabricated using bipolar technology since bipolar transistors meet the stringent requirements of analog circuit technology in an outstanding fashion. However, since the production of integrated bipolar circuits is significantly more complex than the fabrication of circuits on the basis of field effect transistors, silicon field effect transistors are also being used more and more frequently for the realization of less demanding analog circuits using silicon technology.

Bipolar transistors based on organic semiconductors have not been demonstrated hitherto. Since the processing of organic semiconductor layers permits the production of field effect transistors, however, the realization of analog circuits with organic semiconductors is also conceivable, in principle. Unfortunately, however, many of the concepts developed in silicon technology for the realization of analog circuits based on field effect transistors cannot be applied to organic semiconductors.

There are essentially two reasons for this. Firstly, only field effect transistors of one charge type, namely p-channel transistors, are available in organic semiconductor technology at the current state of development. The realization of organic n-channel transistors having sufficiently good electrical properties and sufficient long-term stability has hitherto failed owing to the low electron mobilities and owing to the rapid oxidation of organic n-type semiconductors. Field effect transistors of both charge types are available, in principle, in silicon technology, and silicon analog circuits almost always make use of transistors of both charge types.

Secondly, it is difficult to use organic semiconductors to satisfy the extreme requirements that analog circuit technology makes of the stability of the current-voltage characteristic curves of the transistors. The characteristic curves of organic transistors are generally subjected to significant stochastic or systematic temporal variations, and, in contrast to digital circuits, such changes in the current-voltage characteristic curves cannot be afforded tolerance in the case of analog circuits. Consequently, it has not been possible hitherto to realize organic analog circuits having sufficiently good electrical properties.

One particular form of analog circuits includes dynamic analog circuits which are based on the storage of information items in the form of electrical charges on switched capacitors. In silicon technology, analog circuits using switched capacitor technology have for some years been used for various applications. In this case, the capacitors are realized with use of inorganic dielectrics—usually silicon dioxide—and the switching elements are embodied in the form of silicon field effect transistors. An essential feature of switched capacitor technology is the fact that the switching elements can in principle be realized using transistors of only one charge type. That is to say that the availability of p-channel transistors and n-channel transistors is not absolutely necessary. Moreover, the transistors merely perform the function of switches, so that the requirements made of the stability of the current-voltage characteristic curves of the transistors are significantly more relaxed than in static analog circuits.

Although switched capacitor technology has specific advantages over static analog circuits, dynamic analog circuits using silicon technology are used relatively infrequently since generally they operate significantly more slowly than static analog circuits. For many of the applications discussed in connection with organic semiconductors, however, the speed of the circuits is only of secondary importance. Therefore, switched capacitor technology is definitely of interest for the realization of organic analog circuits. The invention also describes, inter alia, how it is possible to realize dynamic analog circuits with the use of organic semiconductors and polymeric or molecular dielectrics using switched capacitor technology.

Switched capacitor technology is suitable, in principle, for realizing a series of circuit types. These include specific filter circuits, for example. Filters are of great importance for example for the modulation and demodulation of signals.

In contrast to static analog circuits, in which the requirements made of the electrical properties of the transistors are enormously stringent, the quality of the capacitors is primarily of crucial importance in switched capacitor technology. The realization of high-quality capacitors in turn principally requires a high-quality dielectric. In silicon technology, thin layers made of silicon dioxide are preferably used for this, said layers being produced at temperatures of between approximately 600° C. and 1000° C. In contrast to silicon technology, organic semiconductor technology is aimed at the use of alternative substrates such as glass or polymer films which permit in general maximum process temperatures of approximately 200° C. on account of their mechanical and thermal properties. Therefore, primarily polymeric and molecular dielectrics are particularly suitable for organic semiconductor technology.

The invention also realizes, inter alia, the production of organic field effect transistors with use of thermally or optically crosslinked polyvinyl phenol or PVP as the gate dielectric. In principle, however, layers made of crosslinked PVP are also outstandingly suitable as a dielectric for capacitors in switched capacitor technology. The thickness of the PVP dielectrics and hence the capacitance of the capacitors can be set precisely and reproducibly over wide ranges through the choice of process conditions. The top and bottom metal electrodes can be defined by photolithographic methods.

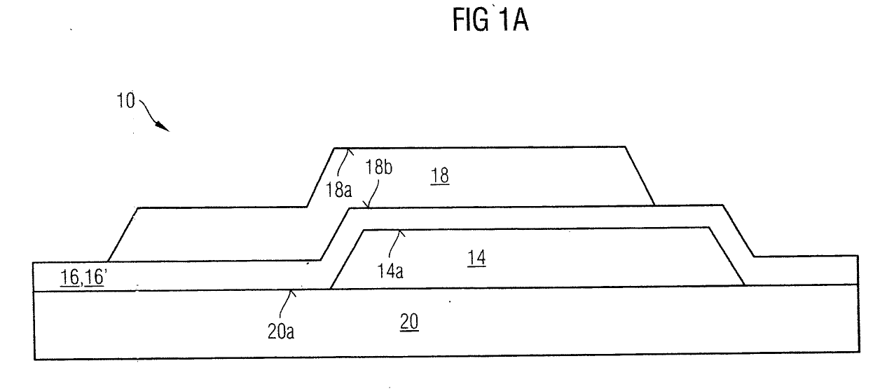

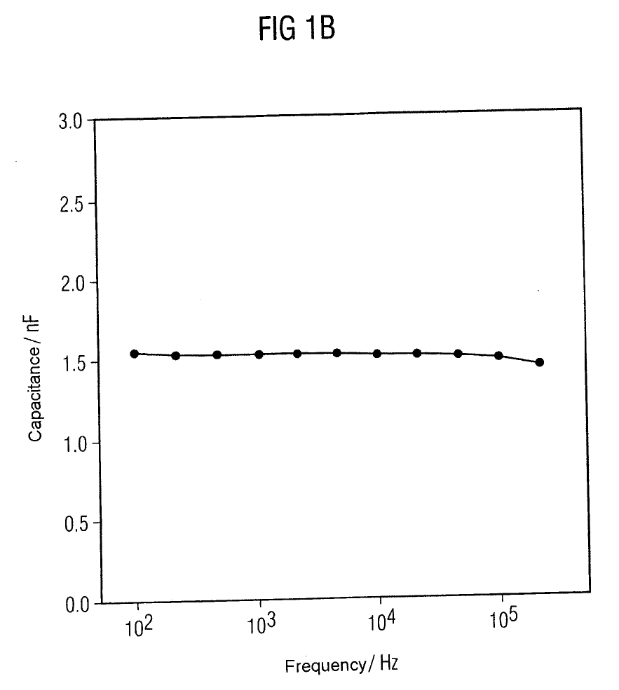

FIGS. 1A and 1B, which are described in greater detail below, show the schematic cross section through a capacitor having metal electrodes and a thermally crosslinked PVP dielectric and, respectively, the characteristic curve of the capacitance of this capacitor as a function of the frequency at which the capacitance is measured. The capacitance is approximately constant over the entire measurement range.

As an alternative to polymeric dielectrics, molecular dielectrics are also outstandingly suitable for providing precise capacitors for organic analog circuits. Materials and methods for producing capacitors on the basis of molecular self-assembled monolayers or so-called SAMs are conceivable, possible and preferably provided according to the invention. In contrast to polymeric dielectrics whose layer thickness is determined by the choice of process conditions and primarily by the concentration of the polymer in the solvent and by the spinning rotational speed, the layer thickness of molecular dielectrics depends solely on the length of the molecules, that is to say solely on the choice of material. Consequently, although the layer thickness of the dielectric can only be set over a relatively small range—corresponding to the length of suitable molecular materials of approximately 2 nm to 5 nm—in return the thickness of the dielectric and hence the capacitance of the capacitor can be set extremely precisely and reproducibly. Molecular dielectrics thus satisfy a significant requirement of switched capacitor technology. Moreover, the relatively small layer thickness of molecular dielectrics permits the production of capacitors with a comparatively small area requirement. By way of example, it is possible to realize a capacitor having a capacitance of 1 pF of an area of 100 μm². As in the case of polymeric dielectrics, the top and bottom metal electrodes can be defined without any problems by photolithographic methods in the case of molecular dielectrics, too.

Field effect transistors on the basis of organic semiconductor layers, for example of pentacene, polythiophene and oligothiophenes, are suitable for realizing the switching elements in switched capacitor technology. As the gate dielectric for the organic field effect transistors, it is possible to use both inorganic and organic materials in the form of thin layers. The polymeric or molecular dielectrics that have already been proposed for realizing the capacitors are suitable, in particular. The invention also proposes, inter alia, materials and processes for realizing organic field effect transistors with polymeric or molecular dielectrics.

The present invention also describes, inter alia, materials and processes for realizing dynamic analog circuits using switched capacitor technology on the basis of organic semiconductor layers, polymeric and/or molecular dielectrics. By virtue of the particular properties of organic materials, these circuits can be integrated on arbitrary substrates—including glass and polymer films.

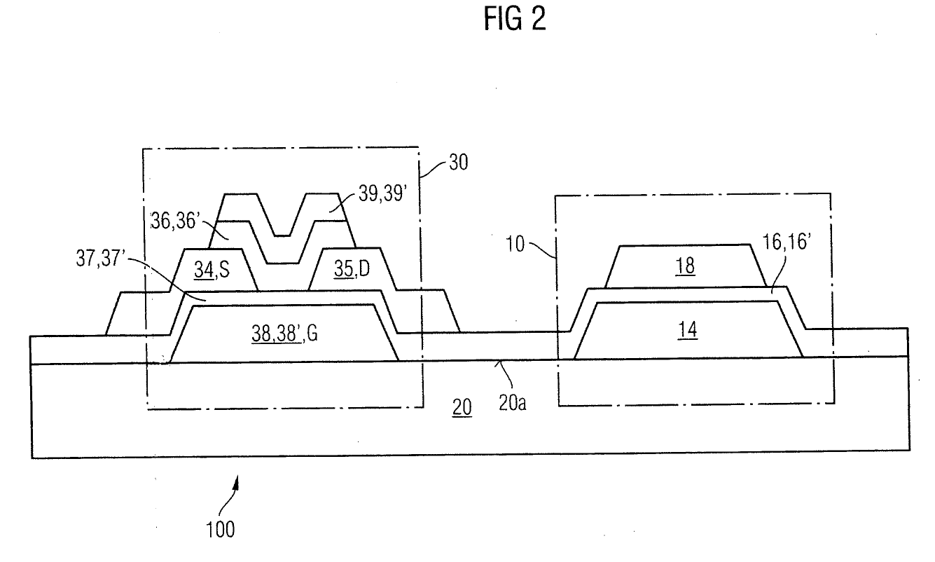

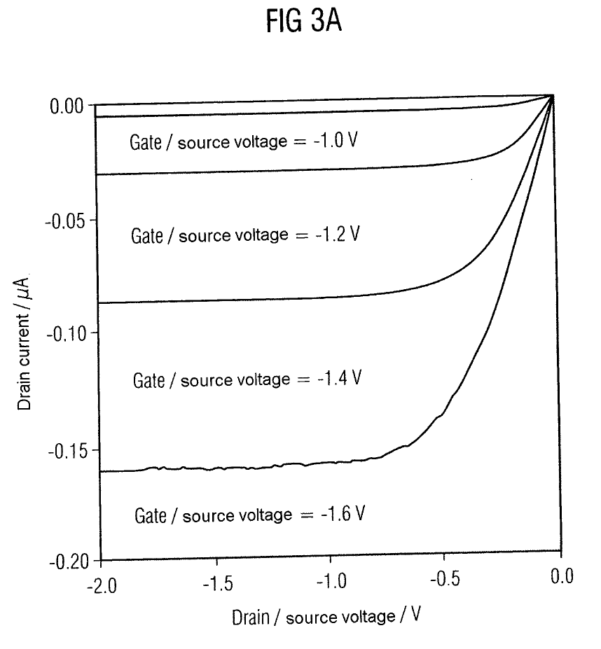

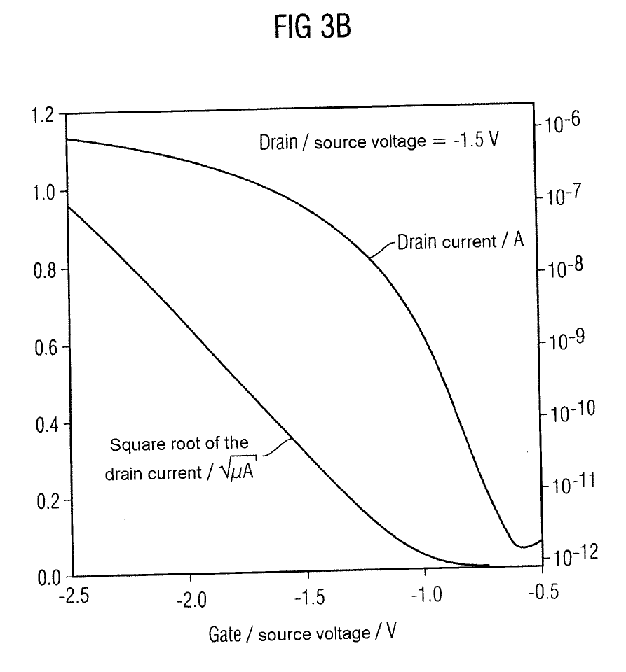

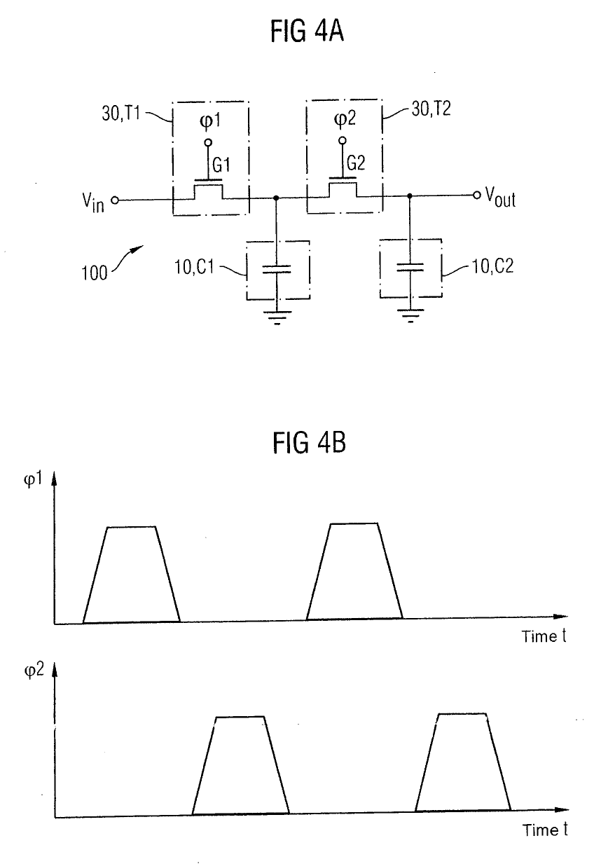

One example is a low-pass filter using switched capacitor technology with organic transistors and molecular dielectrics. On a glass substrate, capacitors and transistors with a molecular dielectric are produced by deposition and patterning of a 20 nm thick layer of aluminum (deposition: vacuum evaporation; patterning: photolithography, wet-chemical etching), a 2.5 nm thick self-assembled monolayer made of octadecylphosphonic acid (deposition: from alcoholic solution; patterning: photolithography and oxygen plasma etching), a 30 nm thick layer of gold (deposition: vacuum evaporation; patterning: photolithography, wet-chemical etching) and a 30 nm thick layer of pentacene (deposition: vacuum evaporation; patterning: photolithography with water-soluble photoresist based on polyvinyl alcohol, oxygen plasma etching). The schematic cross section through an arrangement includes an organic field effect transistor with a molecular gate dielectric and a capacitor with a molecular dielectric is illustrated in FIG. 2 (described in greater detail below). FIG. 3 (described in greater detail below) shows the current-voltage characteristic curves of a pentacene transistor with a gate electrode made of aluminum, a molecular gate dielectric, e.g. octadecylphosphonic acid, and source and drain contacts made of gold. FIGS. 4A and 4B, which are described in greater detail below, show the circuit diagram and the phase diagram, respectively of a low-pass filter using switched capacitor technology.

According to the invention, a capacitor including a dielectric made, in particular, of a self-assembled monolayer of an organic compound is used in an analog circuit using switched capacitor technology.

However, since the capacitance of a capacitor depends on the layer thickness of the dielectric, to be precise in accordance with the relationship:

$$C = ɛ \cdot \frac{A}{d} ,$$

where C denotes capacitance, ε denotes dielectric constant, A denotes area and d denotes layer density of the dielectric, the use of organic monolayers yields particularly suitable capacitor devices, and conversely a large layer thickness inevitably leads to a small specific capacitance.

Therefore, the present invention relates to the use of a capacitor in an analog circuit using switched capacitor technology including a first electrode, a second electrode and a dielectric layer arranged between the first and second electrodes, said dielectric layer essentially being formed from a monolayer of an organic compound having a linker chain, an anchor group and, if appropriate, a head group.

The advantages of the capacitor used according to the invention over the prior art are that the capacitor according to the invention can be produced by a simple method and can be used on arbitrary substrates with use of organic self-assembled monolayers as the capacitor dielectric. The construction of the thin-film capacitors is effected e.g. according to a conventional layer construction, e.g. in the form of electrode-dielectric-electrode, it being possible for the three layers to be produced one after the other using evaporation processes, printing processes or dipping processes. The evaporation temperatures of the organic compounds which form the dielectric monolayer on the electrode surface are particularly favorable for deposition on flexible substrates, since the temperature at which the deposition is effected is generally less than 200° C. The layer thickness of the dielectric is merely the thickness of a monolayer and corresponds approximately to the molecular length, with the result that it lies in the range of approximately 2 nm to 10 nm and on this basis outstanding electrical properties of the capacitor according to the invention can be achieved.

What is essential to the outstanding dielectric properties is, e.g., the molecular design of the organic compound including the anchor group, linker chain and head group. The reactive anchor group has the task of binding the molecule to the electrode surface by a preferably covalent bond, which results in particularly high thermal, mechanical and chemical stability of the monolayer.

The linker chain, which is preferably formed from an n-alkyl chain or an ether chain, brings about a virtually orthogonal orientation and hence a densest possible packing of the molecules. The head group, which preferably has a π system or some other radical capable of intermolecular interactions, serves for stabilizing the monolayer by using said intermolecular interactions or ππ interactions to make molecules interact to an increased extent with their respective neighbors and consequently be additionally stabilized mechanically and electrically. As a consequence, such layers are better insulators than comparable monolayers without corresponding head groups.

One particular advantage of the materials provided according to the invention is the variability with respect to the electrode material through the choice of suitable reactive anchor groups. Thus, in principle, all metals or alloys or semimetals which have a natural oxide layer and/or can be superficially oxidized in a simple manner are suitable as electrode material. Furthermore, other metals and their alloys that are capable of forming covalent bonds or other strong interactions with organic reactive groups, such as, for example, gold, silver, copper and gallium arsenide in the case of thiol anchor groups, are also suitable as electrode material.

To summarize, it can be stated that the capacitor provided according to the invention enables technically simple integration on arbitrary substrates such that the production of capacitors with a comparatively small area requirement is possible, since the layer thickness of the dielectric layer is in the nanometers range, and such that there is high variability in the choice of electrode materials.

In one particular embodiment, the layer thickness of the dielectric according to the invention has the length of a single molecule and is in the range of approximately 1 to approximately 10 nm. The length of the molecule is intended to enable an orthogonal orientation, with the result that it is very difficult for shorter molecules that are less than 1 nm to form a monolayer. In the case of the molecules that are longer than 10 nm, it is difficult to obtain the orthogonal orientation owing to many degrees of freedom. In one preferred embodiment, the layer thickness in the range of approximately 2 nm to approximately 5 nm is particularly advantageous.

As already mentioned above, the head group may in principle be any group that enables an intermolecular interaction between two molecules. According to the invention, π systems may serve as the head group, since a ππ interaction can arise as a result, which contributes to the stabilization of the monolayer. The π systems according to the invention may also be substituted by heteroatoms.

All groups that enable an orthogonal orientation of the molecule and keep the distance between the head group and the anchor group stable are suitable as linker groups. In one particular embodiment of the invention, the linker chains are formed from n-alkyl chains or polyether chains. The π-alkyl or polyether chains have repeat units —(CH₂)ₙ— or —(O—CH₂—CH₂)ₙ—, with n in the range of approximately 2 to 20 for the n-alkyl chain and in the range of 2 to 10 for the polyether chain.

As already described above, the electrodes may be composed of all metals or metal alloys or semimetals, where the electrode material preferably enters into a covalent bond with the anchor group. However, some other interaction such as e.g. ionic interaction, hydrogen bridges or charge transfer interaction, is also taken into consideration.

Aluminum, titanium, gold, silver, copper, palladium, platinum, nickel, silicon and gallium arsenide are particularly preferred for the electrode materials. If the electrode material is composed of aluminum or titanium, the surface can be oxidized in a simple manner in order to be able to react with anchor groups. R—SiCl₃; R—SiCl₂—alkyl, R—SiCl(alkyl)₂; R—Si(OR)₃; R—Si(OR)₂—alkyl; R—SiOR(alkyl)₂ and/or R—PO(OH)₂ are then taken into consideration with particular preference as anchor groups.

If silicon with a native or deliberately produced silicon oxide layer, such as, for example, hydroxy-terminated silicon, is used, R—SiCl₃; R—SiCl₂—alkyl; R—SiCl(alkyl)₂; R—Si(OR)₃; R—Si(OR)₂—alkyl; R—SiOR(alkyl)₂ are particularly preferred as anchor groups.

If silicon with a hydrogen surface is used as the electrode material, R—CHO(hv) and R—CH═CH₂(hv) are particularly preferred.

For the second electrode, which does not have to enter into a covalent bond with the self-assembled monolayer, in principle all electrically conductive materials are suitable, in particular metals and conductive polymers.

Since the deposition of the organic molecules which form the dielectric monolayer on the electrode surface is particularly gentle, and very suitable for flexible substrates, in one preferred embodiment the capacitor according to the invention is incorporated into flexible substrates.

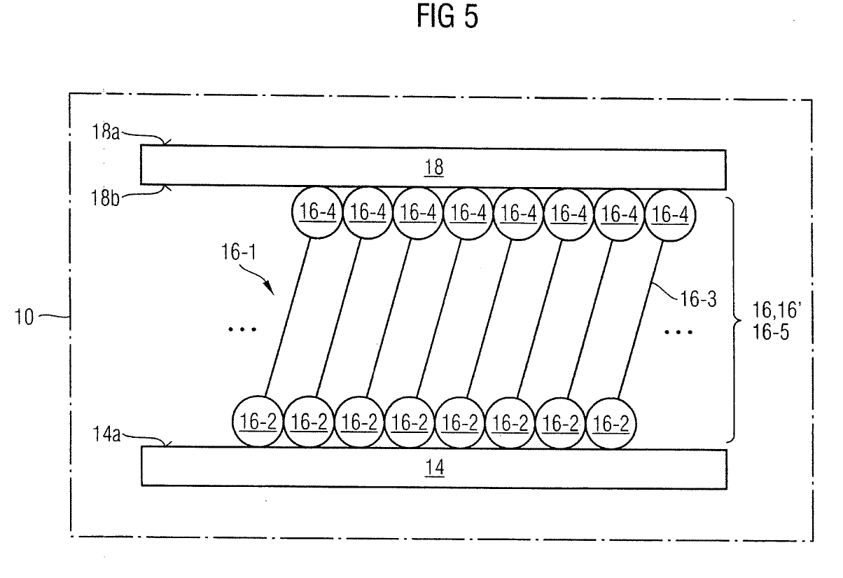

The schematic construction of the capacitor according to the invention is depicted in FIG. 5 (described in greater detail below). Situated between two electrodes is a layer of an organic molecule which enters into a covalent bond with an electrode, has a virtually orthogonal orientation between two electrodes, and is stabilized by the π system in the case of the second electrode. The first electrode is composed of natively oxidized silicon and the second electrode is composed of gold.

The capacitor according to the invention is produced by depositing the first electrode, bringing the first electrode into contact with the organic compound in order to obtain a self-assembled monolayer of the compound on the first electrode, if appropriate rinsing the structure thus obtained with the solvent in which the compound was dissolved, in order to remove the excess compound, evaporating the solvent and depositing the second electrode.

The rinsing of the excess compound is effected only when the compound is dissolved in a solvent. In one preferred embodiment, the compound in solution is brought into contact with the first electrode, other methods for depositing the organic compounds also being possible.

The concentration of the organic compound of which the solution is brought into contact with the first electrode is preferably between approximately 10⁻⁴ and 1 percent by weight. This concentration in the range of approximately 10⁻⁴ to I percent by weight is suitable in particular for producing dense layers. However, it is also possible to use less concentrated or highly concentrated solutions of the organic compounds. The deposition can then be achieved by immersing the substrate with a defined first electrode into the prepared solution, after which the rinsing with the pure process solvent can be achieved. Optionally, the structure thus obtained may be implemented using a readily volatile solvent such as, for example, acetone or dichloromethane and subsequent drying under inert gas. The preferred solvents for dissolving the organic compound are dried, low-polarity, aprotic solvents.

By way of example, such solvents are toluene, tetrahydrofuran or cyclohexan.

If the organic compound is brought into contact with the first electrode from the gas phase, the pressure is preferably between 10⁻⁶ and approximately 400 mbar and essentially depends on the volatility of the organic compound.

The method temperature is preferably in the range of approximately 80 to 200° C. and the deposition time lies between approximately 3 min and 24 h.

If the molecular self-assembled monolayer is obtained, the second electrode can be deposited by vapor deposition.

FIG. 1A shows, in the form of a schematic sectional side view, a first embodiment of an integrated capacitor device 10 according to the invention. This integrated capacitor device is formed on the surface 20a of a substrate 20 and includes a first or bottom electrode device 14, to be precise in the form of a metal electrode, e.g. made of aluminum or the like, a second or top electrode device 18 arranged above the first or bottom electrode device, to be precise also in the form of a metal electrode, and a dielectric region 16 made of an organic dielectric material 16′ (e.g., in the form of a polymer dielectric) provided in between the electrode devices.

FIG. 1B shows, in the form of a graph in which the frequency of a charging/discharging current is illustrated on the abscissa and in which the capacitance of the integrated capacitor device 10 shown in FIG. 1 is illustrated on the ordinate, the capacitor capacitance as a function of the frequency of the charging/discharging current. It becomes clear that the capacitance of the integrated capacitor device illustrated in FIG. 1A is approximately constant in the range between 10² and 10⁵ Hz, to be precise at a value of approximately 1.5 nF.

FIG. 2 shows, in a schematic and sectional side view, an integrated circuit arrangement 100, and in particular an integrated analog circuit 100 with a capacitor device 10 according to the invention and a field effect transistor device 30 that is likewise provided, both of which are formed and provided on or in the surface region 20a of an underlying substrate 20. In a manner analogous to that in the case of the embodiment of FIG. 1A, the capacitor device 10 of the embodiment of FIG. 2 includes a first or bottom electrode 14, a second or top electrode 18, and also a dielectric region 16 provided in between the electrodes and made of an ultra thin self-assembling monolayer, which is also referred to as an SAM or self-assembled monolayer. The ultra thin self-assembling monolayer forms the organic material 16′ for the dielectric region 16.

The field effect transistor device 30 includes a gate region—provided directly on the surface region 20a of the substrate 20—in the form of a gate electrode G, 38 made of a gate electrode material 38′. Provided above the gate electrode are a source electrode S as first electrode device 34 of the field effect transistor device 30, a drain electrode D as second electrode device 35 of the field effect transistor device 30 and, in between, a channel region 36 made of a channel material 36′. A passivation layer 39 made of a passivation material 39′ is formed above the channel region 36 with the channel material 36′. Provided between the gate electrode G as third electrode device 38 of the field effect transistor device 30 made of a corresponding electrode material 38′, on the one hand, and the source electrode S, the drain electrode D and the channel material 36′ for the channel region 36, here in the form of an active pentacene TFT layer, on the other hand, is an insulating gate insulation layer 37 made of a corresponding organic material 37′, which is formed by the same layer as that of the organic material 16′ for the dielectric region 16 for the integrated capacitor device 10 according to the invention (that is to say, e.g., an ultra thin self-assembling monolayer as dielectric). The pentacene field effect transistor 30 of the embodiment of FIG. 2 which is formed in this way thus has a molecular gate dielectric 37, 37′ in this case.

FIGS. 3A and 3B show, in the form of corresponding graphs, current-voltage characteristic curves of the pentacene field effect transistor 30 shown in FIG. 2.

In the graph of FIG. 3A, the drain current is plotted as a function of the drain/source voltage, to be precise for four different gate-source voltages, namely −1.6 V, −1.4 V, −1.2 V and −1.0 V.

In the graph of FIG. 3B, on the right-hand side the drain current is plotted as a function of the gate/source voltage, and on the left-hand side the square root of the drain current is plotted as a function of the gate/source voltage, to be precise in each case for a drain/source voltage of −1.5 V.

FIG. 4A shows, in a schematic view in the form of a circuit diagram, an embodiment of the analog circuit arrangement 100 according to the invention in the form of a low-pass filter using switched capacitor technology. In this case, two field effect transistor devices 30 are provided, which are designated by T1 and T2 and are each assigned an integrated capacitor device 10 (designated as C1 and C2) in accordance with the invention.

The graphs of FIG. 4B show the control potential profiles φ1 and φ2 that are applied to the gate regions G1 and G2 of the field effect transistor devices T1 and T2, as a function of time.

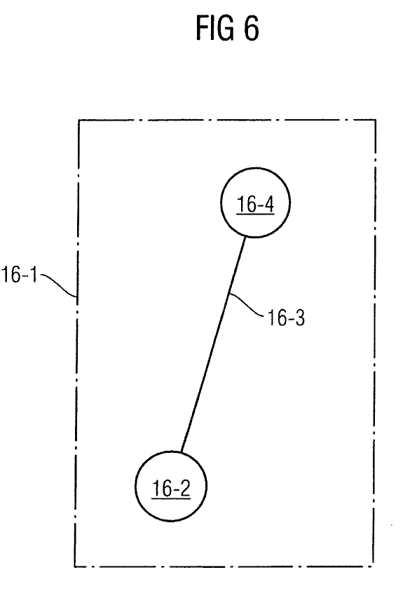

FIG. 6 illustrates schematically and by way of example the fact that the respective molecule 16-1 of the arrangement of the organic material 16′ for the dielectric region 16 has an essentially linear extent, each molecule 16-1 having a linear region 16-3 with functional groups 16-2 and 16-4 at the opposite ends of the linear region 16-3. The terminal groups or functional groups 16-2 and 16-4 can be provided alternatively or jointly.

In the arrangement shown in a schematic and sectional side view in FIG. 5, with organic material 16′ for the dielectric region 16 of an embodiment of the integrated capacitor device according to the invention, the first terminal groups or functional groups 16-2 of the molecules 16-1 interact with the surface region 14a of the first or bottom electrode 14, whereas the second terminal groups or functional groups 16-4 interact with the underside 18b of the second or top electrode device 18, to be precise in such a way as to result in a self-assembling monolayer 16-5 for the arrangement of the molecules 16-1 of the dielectric region 16 in the case of which the individual molecules 16-1 are arranged in densely packed fashion in particular two-dimensionally in quasi crystalline fashion, and if appropriate have a common inclination relative to the normal surface 14a and to the underside 18b, respectively.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### List of Reference Symbols

10 Integrated capacitor device
14 First or bottom electrode device
14a Surface region, top side
16 Dielectric region
16′ Organic material for dielectric region 16
16-1 Molecule
16-2 First or lower terminal group, first or lower functional group
16-3 Linear region of the molecule 16-1
16-4 Second or upper terminal group, second or upper functional group
16-5 Monolayer
18 Second or top electrode device
18b Underside
20 Substrate
20a Surface region
30 Field effect transistor device, transistor device
34 Source electrode
35 Drain electrode
36 Channel region
36′ Organic material for channel region 36, gate material
37 Gate insulation region
37′ Organic material for gate insulation region 37
38 Gate electrode
38′ Material for gate electrode 38
100 Invention's integrated analog circuit arrangement, integrated analog circuit
C1 First integrated capacitor device
C2 Second integrated capacitor device
D Drain region
G Gate electrode
G1 Gate electrode
G2 Gate electrode
S Source region
T1 First integrated field effect transistor device
T2 Second integrated field effect transistor device
φ1 Control signal, control potential
φ2 Control signal, control potential

What is claimed:

1. An integrated analog circuit using switched capacitor technology, comprising:
an integrated capacitor device; and
a transistor device that is connected to the integrated capacitor device, wherein the integrated capacitor device includes a first electrode device, a second electrode device, and a dielectric region provided between the first electrode device and the second electrode device, the dielectric region being formed with or from at least one organic material.

2. The integrated analog circuit of claim 1, wherein the organic material of the dielectric region is formed with or from at least one organic polymeric material.

3. The integrated analog circuit of claim 1, wherein the organic material of the dielectric region is formed with or from at least one organic molecular material including at least one self-assembled monomolecular layer.

4. The integrated analog circuit of claim 1, wherein the organic material of the dielectric region is formed with or from at least one thermally crosslinked organic material.

5. The integrated analog circuit of claim 1, wherein the organic material of the dielectric region is formed with or from at least one optically crosslinked organic material.

6. The integrated analog circuit of claim 1, wherein at least one of the first electrode device and the second electrode device is formed with or from at least one metallic material.

7. The integrated analog circuit of claim 1, wherein the circuit is formed on or in a surface region of a substrate.

8. The integrated analog circuit of claim 7, wherein the substrate is formed with or from at least one material selected from the group consisting of a glass, a mechanically flexible material, a film and a polymer film.

9. The integrated analog circuit of claim 1, wherein the transistor device is formed with or from at least one organic material.

10. The integrated analog circuit of claim 1, wherein the transistor device is formed with a channel region made from or with at least one organic material formed from at least one of pentacene, polythiophene and oligothiophene.

11. The integrated analog circuit of claim 1, wherein a gate insulation region is formed between a channel region and a gate electrode of the transistor device, the gate insulation region being made from at least one organic material formed from at least one of a polymeric organic material, a molecular organic material and a self-assembling monolayer.

12. The integrated analog circuit of claim 1, wherein the circuit is formed as a low-pass filter.

13. A method for producing an integrated analog circuit using switched capacitor technology, the method comprising:
forming an integrated analog circuit with a capacitor device and a transistor device that is connected to the capacitor device;
wherein the capacitor device includes a first electrode dielectric region, a second electrode region, and a dielectric region between the first electrode device and the second electrode device, the dielectric region being formed with or from at least one organic material.

14. The method of claim 13, wherein the organic material of the dielectric region is formed with or from at least one organic polymeric material.

15. The method of claim 13, wherein the organic material of the dielectric region is formed with or from at least one organic molecular material including at least one self-assembled monomolecular layer.

16. The method of claim 13, wherein the organic material of the dielectric region is formed with or from at least one thermally crosslinked organic material.

17. The method of claim 13, wherein the organic material of the dielectric region is formed with or from at least one optically crosslinked organic material.

18. The method of claim 13, wherein at least one of the first electrode device and the second electrode device is formed with or from at least one metallic material.

19. The method of claim 13, further comprising:
forming the circuit on or in a surface region of a substrate.

20. The method of claim 19, wherein the substrate is formed with or from at least one material selected from the group consisting of a glass, a mechanically flexible material, a film and a polymer film.

21. The method of claim 13, wherein the transistor device is formed with or from at least one organic material.

22. The method of claim 13, wherein the transistor device is formed with a channel region made from or with at least one organic material formed from at least one of pentacene, polythiophene and oligothiophene.

23. The method of claim 13, wherein a gate insulation layer is provided between a channel region and a gate electrode of the transistor device, the gate insulation region being made with or from at least one organic material formed from at least one of a polymeric organic material, a molecular organic material and a self-assembling monolayer.

24. The method of claim 13, wherein the circuit is formed as a low-pass filter.
